(19) United States
(12) Patent Application Publication
(10) Pub. No.: US 2013/0199602 A1
(43) Pub. Date: Aug. 8, 2013

(54) SOLAR CELL WITH MICROSTRUCTURE THEREIN

(71) Applicants: Wen-Chi Hou, Tainan City (TW); Tung-Hsien Wu, Tainan City (TW); Chih-Jui Ni, Tainan City (TW); Jyong-Sian Tsai, Tainan City (TW); Wen-Yi Tsai, Tainan City (TW); Chau-Nan Hong, Tainan City (TW)

(72) Inventors: Wen-Chi Hou, Tainan City (TW); Tung-Hsien Wu, Tainan City (TW); Chih-Jui Ni, Tainan City (TW); Jyong-Sian Tsai, Tainan City (TW); Wen-Yi Tsai, Tainan City (TW); Chau-Nan Hong, Tainan City (TW)

(73) Assignee: Bureau of Energy Ministry of Economic Affairs, Taipei City (TW)

(21) Appl. No.: 13/365,910

(22) Filed: Feb. 3, 2012

(51) Int. Cl. H01L 31/0264; H01L 31/06

(52) U.S. Cl. 136/255; 136/262

(57) ABSTRACT

A solar cell includes a substrate; multiple silicon rods formed on a surface of the substrate; an insulator layer formed on the surface of the substrate while the silicon rods are still exposed; a silicon shell layer formed on outside of each of the silicon rods; and a InₓGa₁₋ₓAs_{y}P_{1-y} layer formed on the silicon shell layer to form a first cell, wherein 0≦x≦1 and 0≦y≦1.

### BACKGROUND OF THE INVENTION

1. Field of the Invention

The present invention relates to a solar cell, and more particularly, to a solar cell having therein a 3D microstructure.

2. Description of the Prior Art

In U.S. publication 2011/0041900A1, a solar cell is disclosed and has multiple nano-wires arranged in such a way that the diameter of the nano-wires increases following the incident light path, a coating layer coated upon the nano-wires to form a p-n connection with the nano-wires, a first electrode electrically connected to the nano-wires and a second electrode electrically connected to the coating layer.

Another solar cell is disclosed in U.S. publication 2011/0023948A1 and includes a substrate, a nanowire formed on a surface of the substrate and an electrode coupled with the nanowire. The nanowire is electrically conductive and capable of absorbing electromagnetic wave to generate current.

Still another solar cell is described in U.S. publication 2010/0313953A1 to have a first electrode, a conductive membrane electrically coupled and supported to the first electrode, multiple absorptions capable of absorbing crystallized light, electrical holes located between the conductive membranes to be responsible for transferring matters, and an electrode electrically coupled to the electrical holes.

Of all the described solar cells, none of which is able to solve the problem of thermal expansion coefficient (TEC) and the problem of lattice constant (LC) mismatch. With the mismatch of TEC and LC, cleavage and high dislocation density may easily happen between nanostructures.

### SUMMARY OF THE INVENTION

One preferred embodiment of the present invention provides a solar cell made of InₓGa₁₋ₓAs_{y}P_{1-y}. In this InₓGa₁₋ₓAs_{y}P_{1-y} solar cell, single-crystal or mono-crystalline rods are first formed on a substrate. Then an epitaxial growth is processed on the outside of the single crystal rods to form a first cell of p or n type conductivity photovoltaic cell or p, intrinsic and n type conductivity photovoltaic cell.

Another preferred embodiment of the present invention provides a solar cell having single crystal rods formed on a substrate, a first cell of p or n type conductivity formed on the outside of the rods and a second cell formed on the first cell to have p and n type or p, intrinsic and n type conductivity and made of InₓGa₁₋ₓAs_{y}P_{1-y}, wherein 0≦x≦1 and 0≦y≦1.

Still another objective to be accomplished according to another embodiment of the present invention is that a tunneling junction layer may be inserted between the first cell and the second cell to help transfer of electrons and holes between the first cell and the second cell.

Multiple second cells of different band gaps compared with the very first second cell and of InₓGa₁₋ₓAs_{y}P_{1-y} may be formed on top of the very first second cell.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a side plan view showing an ordinary substrate to be used in the preferred embodiment of the present invention;

FIG. 2 is a side plan view showing that silicon rods are formed on a surface of the substrate as shown in FIG. 1;

FIG. 3 is a side plan view showing that an insulator layer is formed on the surface of the substrate;

FIG. 4 is a side plan view showing that a silicon shell layer is formed on the outside of each of the silicon rods;

FIG. 5 is a side plan view showing that an InₓGa₁₋ₓAs_{y}P_{1-y} cell is formed; and

FIG. 6 is a side plan view showing that two electrode are respectively formed on top of the photovoltaic cell and on bottom of the substrate as shown in FIG. 5.

### DETAILED DESCRIPTION OF THE INVENTION

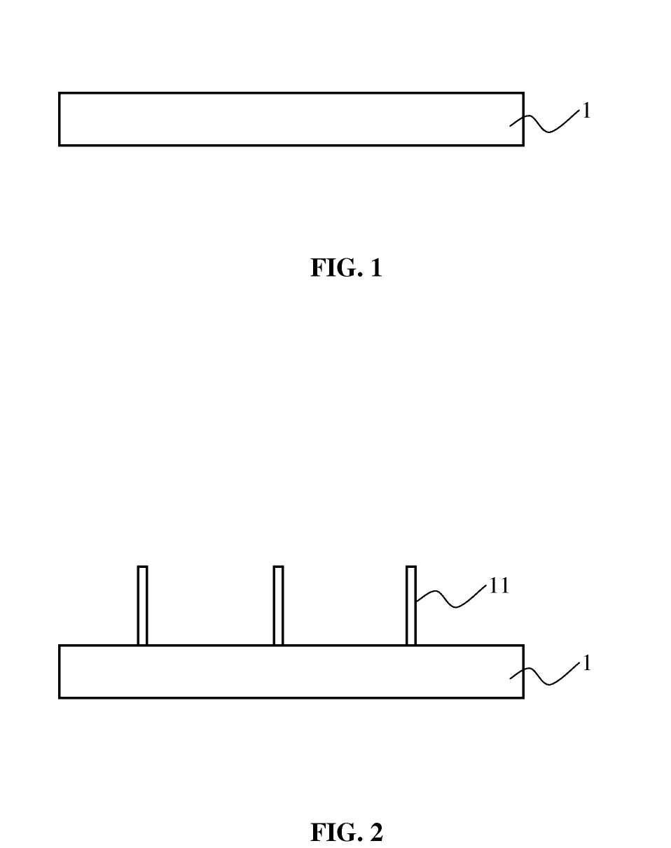

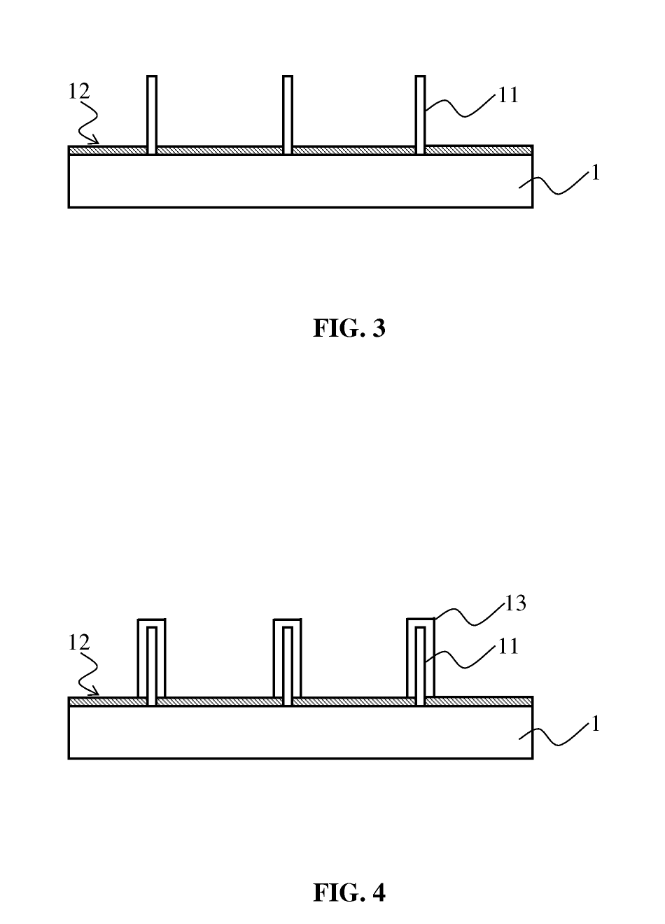

With reference to FIGS. 1 to 4, it is noted that an ordinary substrate 1 of single crystal silicon is presented. An etching process or a chemical vapor deposition (CVD) is implemented on the top surface of the silicon substrate 1 to form multiple microstructures (silicon rods 11). After the silicon rods 11 are formed on top of the substrate 1, a coating process is implemented to form an insulator layer 12, such as SiO₂, on the top surface of the substrate 1 and then a selective removal of a portion of the insulator layer 12 is processed to expose the silicon rods 11. It is noted that a thermal oxide process may alternatively be implemented to form the insulator layer 12.

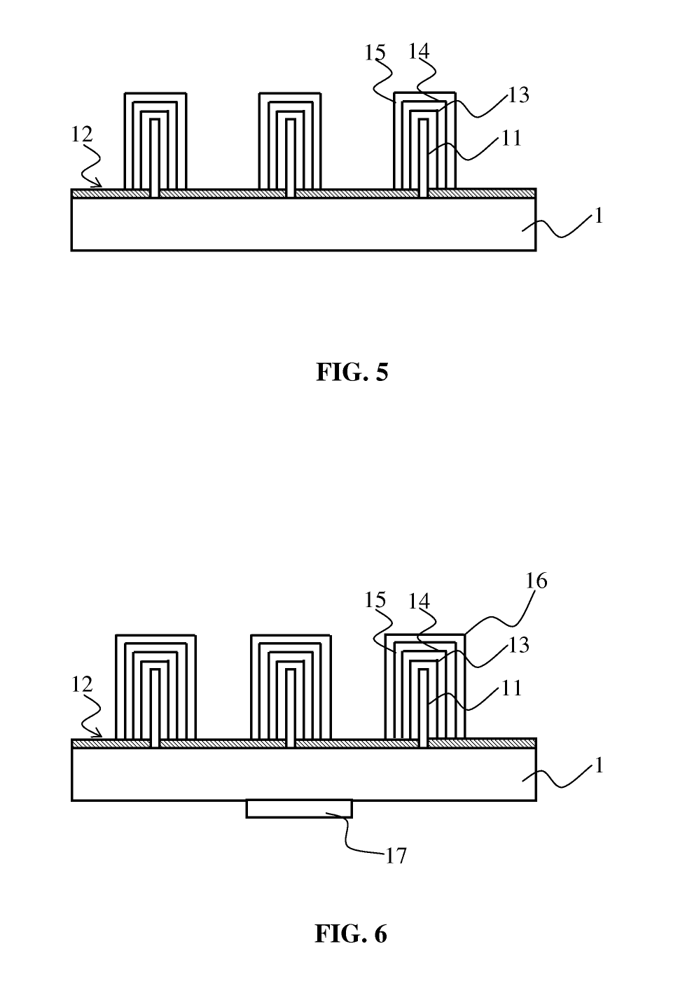

Afterwards, a CVD process is performed to form a silicon shell layer 13 on the outside of each of the silicon rods 11. As shown in FIGS. 5 and 6, an InₓGa₁₋ₓAs_{y}P_{1-y} material, wherein 0≦x≦1 and 0≦y≦1, is formed on the outside of the silicon shell layer so as to form an InₓGa₁₋ₓAs_{y}P_{1-y} photovoltaic cell 14. A second InₓGa₁₋ₓAs_{y}P_{1-y} material 14 may be formed on the outside of the first InₓGa₁₋ₓAs_{y}P_{1-y} material to form a second InₓGa₁₋ₓAs_{y}P_{1-y} photovoltaic cell 15. The first cell being of p or n type conductivity is formed on the outside of the rods 11 and a second cell is formed on the first cell to have p and n type or p, intrinsic and n type conductivity and made of InₓGa₁₋ₓAs_{y}P_{1-y}, wherein 0≦x≦1 and 0≦y≦1. Thereafter a deposition process is performed to form a top electrode 16, i.e., Indium Tin Oxide, ITO, on the outside of the first InₓGa₁₋ₓAs_{y}P_{1-y} photovoltaic cell 14, and another deposition process is performed to form a bottom electrode 17, i.e., Indium Tin Oxide, ITO, on the bottom surface of the substrate 1.

With the structure as described earlier, it is noted that because the silicon rod is a single crystal silicon rod and the first cell is a homoepitaxy to the silicon rod. Together, the two can be treated as a mono-crystalline silicon. Those later-formed photovoltaic cells are heteroepitaxy when compared with the silicon rods. Due to the nature of the silicon rods and the first cell being the same, the lattice constant and the thermal expansion coefficient are compatible. As such, problems like cleavage and high dislocation density are obviated and the lifespan of the solar cell is extended.

Those skilled in the art will readily observe that numerous modifications and alterations of the device and method may be made while retaining the teachings of the invention.

What is claimed is:

1. A solar cell comprising:
a substrate;
multiple silicon rods formed on a surface of the substrate;
an insulator layer formed on the surface of the substrate while the silicon rods are still exposed;
a silicon shell layer formed on outside of each of the silicon rods; and
an InₓGa₁₋ₓAs_{y}P_{1-y} layer formed on the silicon shell layer to form a first cell, wherein 0≦x≦1 and 0≦y≦1.

2. The solar cell as claimed in claim 1, wherein the first cell has a conductivity of p, n or p, intrinsic and n type.

3. The solar cell as claimed in claim 1, wherein a second cell formed on outside of the first cell has a conductivity of p and n type or p, intrinsic and n type.

4. The solar cell as claimed in claim 2, wherein a second cell formed on outside of the first cell has a conductivity of p and n type or p, intrinsic and n type.

5. The solar cell as claimed in claim 3 further comprising a tunneling junction layer located between the first cell and the second cell to help transfer of electrons and holes.

6. The solar cell as claimed in claim 4 further comprising a tunneling junction layer located between the first cell and the second cell to help transfer of electrons and holes.

7. The solar cell as claimed in claim 3 further comprising an electrode formed on top of the second cell.

8. The solar cell as claimed in claim 4 further comprising an electrode formed on top of the second cell.

9. The solar cell as claimed in claim 5 further comprising an electrode formed on top of the second cell.

10. The solar cell as claimed in claim 6 further comprising an electrode formed on top of the second cell.
